(19) United States
(12) Patent Application Publication
(10) Pub. No.: US 2013/0133930 A1
(43) Pub. Date: May 30, 2013

(54) PRINTED WIRING BOARD

(71) Applicant: FUJIKURA LTD., Tokyo (JP)

(72) Inventor: Hirohito WATANABE, Sakura-shi (JP)

(73) Assignee: FUJIKURA LTD., Tokyo (JP)

(21) Appl. No.: 13/686,562

(22) Filed: Nov. 27, 2012

(30) Foreign Application Priority Data
Nov. 28, 2011 (JP) 2011-258936

(51) Int. Cl. H05K 1/02

(52) U.S. Cl. CPC H05K 1/0281
USPC 174/254

(57) ABSTRACT

Provided is a printed wiring board capable of inhibiting a reinforcing plate from peeling off even when a bending radius is small.

The printed wiring board includes a wiring board main body which includes a bending subject portion which is to be bent about a bending line, and a reinforcing plate which is attached to the wiring board main body, the reinforcing plate includes first and second reinforcing portions which are attached to first and second adjacent portions which are adjacent to the bending subject portion in the wiring board main body, and a connecting portion which is attached to the bending subject portion and integrally connects the first reinforcing portion with the second reinforcing portion, and an opening is formed in the connecting portion.

### BACKGROUND OF THE INVENTION

1. Field of the Invention

The present invention relates to a printed wiring board that includes a reinforcing plate and is to be bent with a small bending radius.

This application is based upon and claims the benefit of priority from Japanese Patent Application No. 2011-258936, filed on Nov. 28, 2011; the entire contents of which are incorporated herein by reference.

2. Description of the Related Art

There is a known flexible printed circuit (FPC) including an FPC main body and a reinforcing plate attached to a portion on a tray side of a flexure of the FPC main body through an adhesive sheet (for example, JP 2010-239109 A). In the FPC, the rigidity of the FPC is ensured through the reinforcing plate, thereby inhibiting the FPC from being corrugated due to a movement of the tray.

The above-mentioned reinforcing plate includes an end portion on the flexure side. When the bending radius of the FPC is small, there is a problem in that a stress is concentrated on the end portion due to the flexures of the FPC main body, and the reinforcing plate peels off the FPC main body.

A subject to be solved by the invention is to provide a printed wiring board capable of inhibiting the reinforcing plate from peeling off even when the bending radius small.

### SUMMARY OF THE INVENTION

[1] A printed wiring board according to the invention includes a wiring board main body which includes a bending subject portion which is to be bent about a bending line, and a reinforcing plate which is attached to the wiring board main body, wherein the reinforcing plate includes first and second reinforcing portions which are attached to first and second adjacent portions which are adjacent to the bending subject portion in the wiring board main body, and a connecting portion which is attached to the bending subject portion and integrally connects the first reinforcing portion with the second reinforcing portion, and an opening is formed in the connecting portion.

[2] In the above invention, an outside width W₀ of the bending subject portion along the bending line may be substantially equal to an outside width W₁ of the connecting portion along the bending line.

[3] In the above invention, the following Inequality (1) may be satisfied.

1/10≦W₂/W₀≦⅓ (1)

Here, W₀ denotes an outside width of the bending subject portion along the bending line, and W₂ denotes a width of the connecting portion along the bending line in the above Inequality (1).

[4] In the above invention, the printed wiring board may be bent in the bending subject portion.

According to the invention, it is possible to inhibit a reinforcing plate from peeling off a wiring board main body, since the reinforcing plate is integrally attached to a first adjacent portion, a bending subject portion, and a second adjacent portion of the wiring board main body.

Further, in the invention, an opening is formed in a portion corresponding to a bending subject portion in a reinforcing plate, and the rigidity is weakened in the corresponding portion and thus, it is possible to deal with a small bending radius.

### BRIEF DESCRIPTION OF THE DRAWINGS

FIG. 1 is a plane view illustrating a printed wiring board in an embodiment of the invention.

FIG. 2 is a bottom view of the printed wiring board illustrated in FIG. 1.

FIG. 3 is a cross-sectional view taken along a line III-III of FIGS. 1 and 2.

FIG. 4 is a cross-sectional view taken along a line IV-IV of FIGS. 1 and 2.

FIG. 5 is a cross-sectional view taken along a line V-V of FIGS. 1 and 2.

### DETAILED DESCRIPTION OF THE PREFERRED EMBODIMENTS

Hereinafter, embodiments of the invention will be described with reference to drawings.

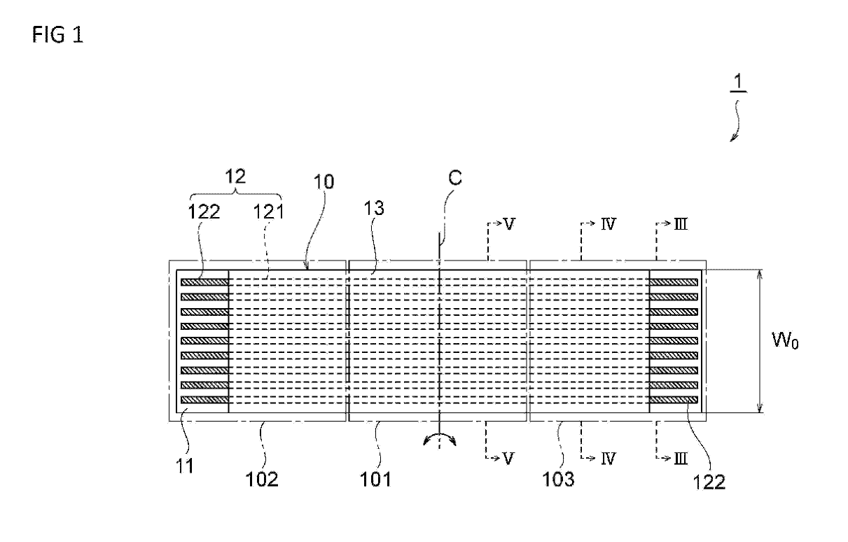

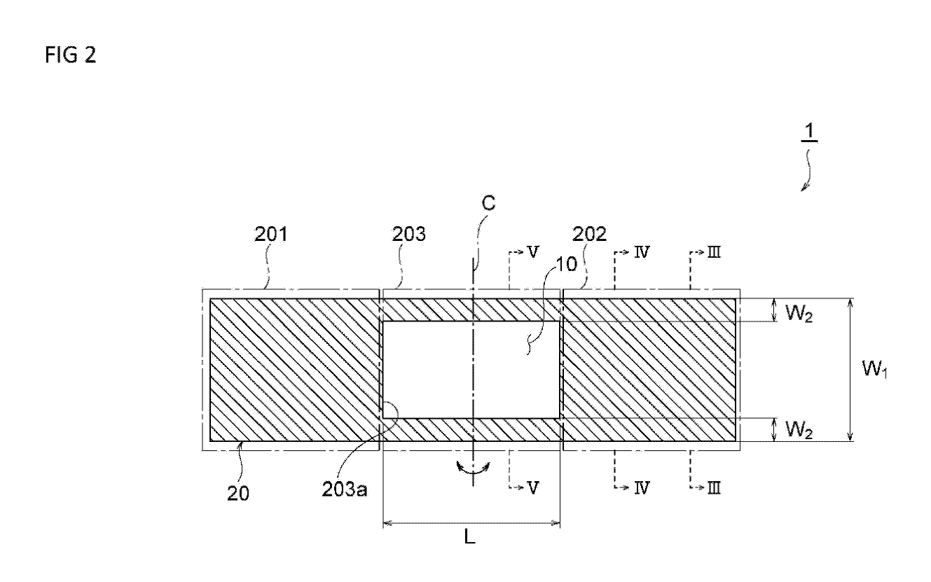

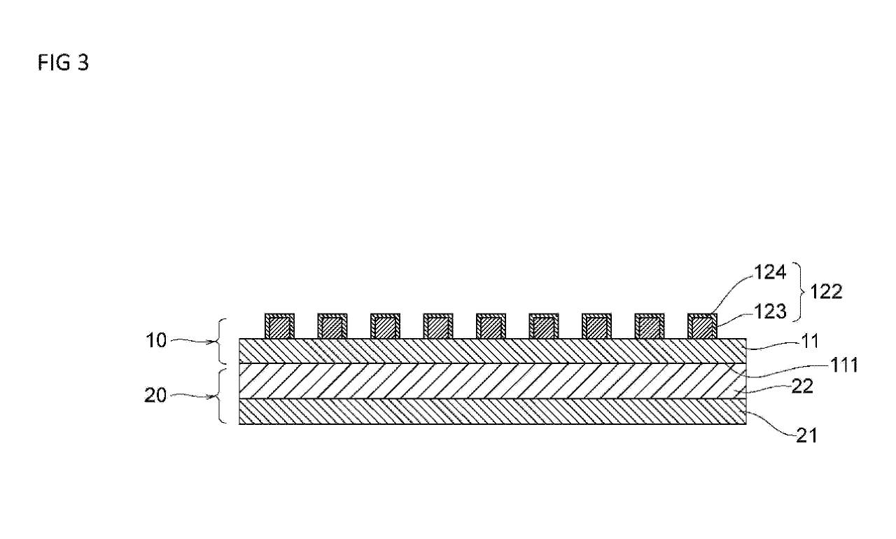

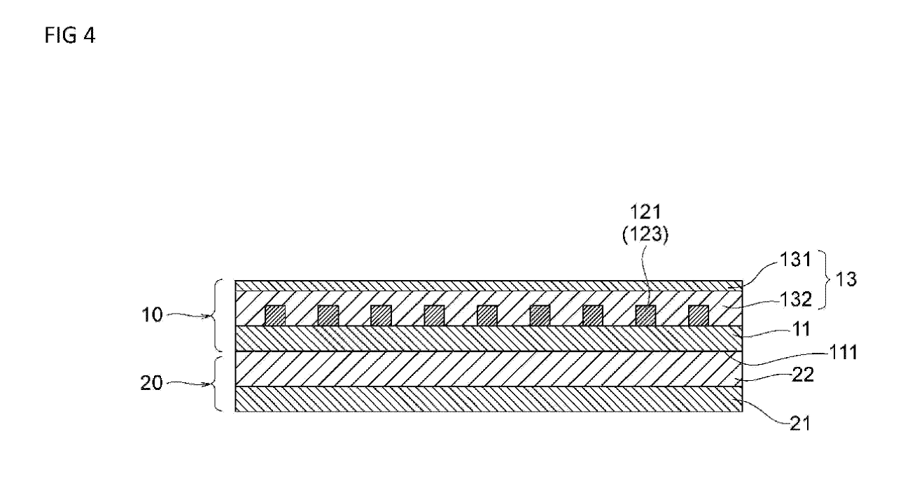

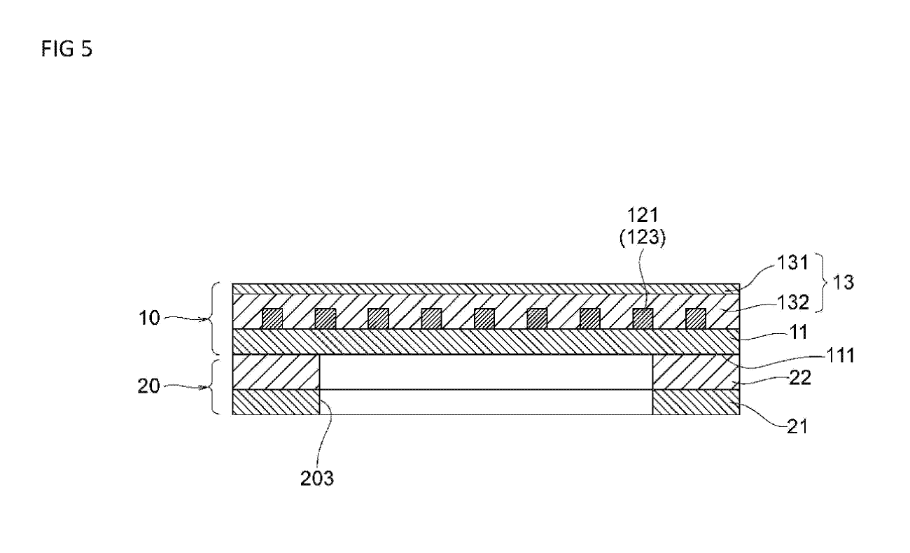

FIGS. 1 and 2 are a plane view and a bottom view illustrating a printed wiring board in an embodiment of the invention, FIG. 3 is a cross-sectional view taken along a line III-III of FIG. 1, FIG. 4 is a cross-sectional view taken along a line IV-IV of FIG. 1, and FIG. 5 is a cross-sectional view taken along a line V-V of FIG. 1.

A printed wiring board 1 in the embodiment is, for example, a flexible printed circuit board (FPC) incorporated in an electronic device such as a mobile phone, a personal digital assistant (PDA), a smart phone, a notebook computer, tablet information terminal, a digital camera, a digital video camera, a digital audio player, a hard disk, and the like.

As illustrated in FIGS. 1 to 5, the printed wiring board 1 includes a wiring board main body 10 and a reinforcing plate 20 attached to the wiring board main body 10, and has a strip shape when viewed as a whole. Moreover, a planar shape of the printed wiring board is not particularly limited, and may be arbitrarily selected.

The wiring board main body 10 includes a base film 11, wiring patterns 12, and a coverlay 13.

The base film 11 is, for example, a flexible insulating film composed of polyimide (PI). Here, the base film 11 may be composed of, for example, liquid crystal polymer (LCP), polyethylene terephthalate (PET), polyethylene naphthalate (PEN), polyester (PE), aramid or the like.

A plurality of wiring patterns 12 are formed on the base film 11. In the embodiment, as illustrated in FIG. 1, the plurality of wiring patterns 12 are arranged parallel to one another at equal intervals, and is linearly extended on the base film 11. Here, a shape, an arrangement, and the like of the wiring patterns 12 are not particularly limited thereto. Further, the wiring patterns may be formed on both surfaces of the base film 11, and a via-hole and the like may be included in the wiring patterns.

Terminals 122 are formed at both ends of the wiring patterns 12 repectively. The terminals 122 are connected to a connector provided in, for example, another printed wiring board, a cable or the like, and the printed wiring board 1 is electrically connected to an external electronic circuit through the terminals 122. Here, a position where the terminals are formed is not limited to an end portion of the wiring patterns, and an arbitrary position in the wiring patterns may be selected. Further, the number of the terminals in the wiring patterns is not particularly limited, and the terminals are not necessarily provided in the wiring patterns.

A portion 121 (hereinafter, simply referred to as a wiring portion 121) other than the terminals 122 in the wiring patterns 12 is formed, for example, by etching a copper foil layered on the base film 11 in a predetermined shape, and is formed only from a copper foil 123 as illustrated in FIGS. 4 and 5.

On the other hand, as illustrated in FIG. 3, the terminals 122 of the wiring patterns 12 includes the copper foil 123 extended from the wiring portion 121, and a plated layer 124 formed on the copper foil 123 by an electroplating process or the like. Although not particularly illustrated, the plated layer 124 has, for example, a nickel (Ni) layer as a base and a gold (Au) layer formed on the Ni layer.

The coverlay 13 includes a resin layer 131 for protecting the wiring portion 121 of the wiring patterns 12 and an adhesion layer 132 that bonds the resin layer 131 to the base film 11 as illustrated in FIGS. 4 and 5, and is layered on the base film 11 so as to cover the wiring portion 121 of the wiring patterns 12 as illustrated in FIG. 1. On the other hand, as illustrated in the same drawing, the terminals 122 of the wiring patterns 12 are exposed from the coverlay 13.

The resin layer 131 of the coverlay 13 is, for example, a flexible insulating base material composed of PI. Here, the resin layer 131 may be composed of, for example, LCP, PET, PEN, PE, aramid or the like.

On the other hand, the adhesion layer 132 of the coverlay 13 is formed from, for example, an epoxy adhesive or an acrylic adhesive. Here, when the base film 11 is composed of LCP, and the resin layer 131 of the coverlay 13 is also composed of LCP, the base film and the resin layer may be attached to each other through a thermal fusion bonding and thus, the adhesive layer 132 is unnecessary.

Here, the coverlay 13 may be formed from a dry film composed of a photosensitive coverlay material using, for example, polyester, epoxy, acryl, polyimide, polyurethane, and the like. Alternatively, the coverlay 13 may be formed by screen-printing on the base film 11, a coverlay ink using polyimide or epoxy as a base, or a liquid photosensitive coverlay material.

As illustrated in FIG. 1, the above-described wiring board main body 10 is incorporated in an electronic device in a state of being bent with a bending radius equal to or less than 0.3 mm about a bending line C, for example. Furthermore, the printed wiring board 1 of the embodiment is permanently incorporated in an electronic device in a state of being bent (plastic-deformed) with an infinitesimal bending radius rather than being incorporated in a movable portion of an electronic device including repeated flexures. Thus, the printed wiring board 1 of the embodiment is required to have toughness for the infinitesimal bending radius rather than bend durability. Moreover, the above-mentioned bending position or bending radius of the printed wiring board is merely an example, and it is not limited thereto.

In the embodiment, as illustrated in FIGS. 2 to 5, the reinforcing plate 20 is attached to a lower surface 111 (a surface opposite to a surface where the wiring patterns 12 are formed in the base film 11) of the base film 11. The reinforcing plate 20 includes a base material 21 reinforcing the wiring board main body 10 and an adhesion layer 22 bonding the base material 21 to the base film 11.

The base material 21 is a plate-like member composed of, for example, a resin material such as PI, LCP, PET, PEN, glass epoxy, aramid or the like, or a metal material such as stainless steel, aluminum, aluminum alloy or the like.

On the other hand, the adhesion layer 22 is composed of, for example, epoxy based or acryl based thermosetting resin. Moreover, the adhesion layer 22 may be formed from a tackifier.

Here, as illustrated in FIG. 1, the wiring board main body 10 includes a bending subject portion 101 that is to be bent about the bending line C, and first and second adjacent portions 102 and 103 positioned on both sides of the bending subject portion 101. As illustrated in FIG. 2, in the embodiment, to correspond to this, the reinforcing plate 20 includes a first reinforcing portion 201, a second reinforcing portion 202, and a connecting portion 203.

The first reinforcing portion 201 is attached to the first adjacent portion 102 of the wiring board main body 10, and the second reinforcing portion 202 is attached to the second adjacent portion 103 of the wiring board main body 10. Further, the connecting portion 203 is attached to the bending subject portion 101 of the wiring board main body 10, and integrally connects the first and second reinforcing portions 201 and 202 with each other.

As described above, in the embodiment, the reinforcing plate 20 is also attached to the bending subject portion 101 of the wiring board main body 10. Accordingly, when the printed wiring board 1 is bent, the bending radius is uniform due to the rigidity of the reinforcing plate 20 and thus, the reinforcing plate 20 is inhibited from peeling off the wiring board main body 10 due to the flexures.

Here, the bending line C is a virtual straight line. Further, the bending subject portion 101 is a portion expected to be bent about the bending line C in the wiring board main body 10, and is a region including the bending line C and a vicinity of the bending line C in the wiring board main body 10. On the other hand, the first and second adjacent portions 102 and 103 are unexpected to be bent, and are portions where, for example, a connector is connected or an electronic component is mounted and thus, are required to have a certain degree of rigidity.

In the embodiment, as illustrated in FIGS. 1 and 2, an outside width W₀ of the bending subject portion 101 of the wiring board main body 10 is substantially equal to an outside width W₁ of the connecting portion 203 of the reinforcing plate 20 (W₀=W₁). Thus, since the reinforcing plate 20 is fixed to the wiring board main body 10 at both ends in a width direction in the bending subject portion 101, the reinforcing plate 20 is difficult to peel off when the printed wiring board 1 is bent.

Further, in the embodiment, as illustrated in FIG. 2, an opening 203a is formed in the connecting portion 203 of the reinforcing plate 20. The outside width W₀ of the bending subject portion 101 of the wiring board main body 10 and a width W₂ of the connecting portion 203 of the reinforcing plate 20 satisfy the following Inequality (1).

1/10≦W₂/W₀≦⅓ (1)

Accordingly, the rigidity of the reinforcing plate 20 may be weakened in the connecting portion 203 and thus, it is possible to deal with a small bending radius.

Here, the terms “outside width” and the “width” in the embodiment refer to a length in a direction along the bending line C.

As described above, in the embodiment, the reinforcing plate 20 is integrally attached to the first adjacent portion 102, the bending subject portion 101, and the second adjacent portion 103 of the wiring board main body 10. Accordingly, it is possible to inhibit the reinforcing plate 20 from peeling off the wiring board main body 10.

Further, in the embodiment, the opening 203a is formed in a portion corresponding to the bending subject portion 101 in the reinforcing plate 20, and the rigidity of the corresponding portion 203 is weakened. Accordingly, it is possible to deal with a small bending radius.

Here, the embodiment in the above is described to facilitate understanding of the invention, and is not described to limit the invention. Accordingly, each component described in the embodiment includes all design changes and equivalents belonging to a technical scope of the invention.

### EXAMPLES

Hereinafter, an effect of the invention is verified through Examples and Comparative Examples further specifically describing the invention. Examples and Comparative Examples below are provided to verify the effect of inhibiting the reinforcing plate from peeling off in the above-described embodiment.

### Example 1

In Example 1, ten strip-shaped printed wiring boards illustrated in FIGS. 1 and 2 described in the embodiment are manufactured as samples.

In particular, first, a strip-shaped single sided CCL (copper clad laminates) in which a copper foil having a thickness of 18 μm is layered on a polyimide film (base film) having a thickness of 25 μm with an adhesive having a thickness of 10 μm interposed therebetween is prepared. Subsequently, a resist pattern is formed on the copper foil, and then an etching process is performed on the copper foil, thereby forming a plurality of linear wiring patterns having a width of 40 μm so as to be parallel to each other at a pitch of 80 μm.

Subsequently, a coverlay in which a thermosetting adhesive having a thickness of 30 μm is applied to a polyimide film having a thickness of 12 μm is layered on the base film so that each of both ends of the wiring patterns is exposed.

Subsequently, a polyimide film having a thickness of 25 μm is layered on a lower surface of the base film with a thermosetting adhesive having a thickness of 30 μm interposed therebetween, and a curing treatment is performed using a hot press, thereby bonding the coverlay, the base film, and the reinforcing plate together.

In Example 1, an outside width W₀ of a bending subject portion of a wiring board main body is set to 5 mm, and an outside width W₁ of a connecting portion of the reinforcing plate is also set to 5 mm. Further, a distance L (that is, a length of the connecting portion) between a first reinforcing portion and a second reinforcing portion in the reinforcing plate is set to 3 mm. Moreover, a width W₂ of the connecting portion of the reinforcing plate is set to 0.5 mm (=W₀/10).

Ten printed wiring boards manufactured as described above are manually bent about a bending line (corresponding to a symbol C in FIGS. 1 and 2) using a mandrel having a diameter of 0.6 mm (bending radius: 0.3 mm) and are plastic-deformed. Thereafter, whether the reinforcing plate peels off is verified through a visual observation using a microscope.

In Example 1, as illustrated in Table 1, peeling off of the reinforcing plate does not occur in all samples. Here, in the “result” section of Table 1, a symbol “1” denotes a case in which peeling off of the reinforcing plate does not occur in ten samples, and a symbol “2” denotes a case in which peeling off of the reinforcing plate occurs in at least one sample out of ten samples.

TABLE 1

| | outside width | width W₂ | | length L | |
|---|---|---|---|---|---|
| | W₀ [mm] of | [mm] of | | [mm] of | |
| | wiring board | connecting | | connecting | |
| | main body | portion | | portion | result |
| Example 1 | 5 | 0.50 | (= W₀/10) | 3 | 1 |
| Example 2 | 5 | 1.67 | (= W₀/3) | 3 | 1 |
| Example 3 | 1 | 0.10 | (= W₀/10) | 1 | 1 |
| Example 4 | 1 | 0.33 | (= W₀/3) | 1 | 1 |
| Example 5 | 1 | 0.10 | (= W₀/10) | 5 | 1 |
| Example 6 | 1 | 0.33 | (= W₀/3) | 5 | 1 |
| Example 7 | 10 | 1.00 | (= W₀/10) | 1 | 1 |
| Example 8 | 10 | 3.33 | (= W₀/3) | 1 | 1 |
| Example 9 | 10 | 1.00 | (= W₀/10) | 5 | 1 |
| Example 10 | 10 | 3.33 | (= W₀/3) | 5 | 1 |

| | | | | |
|---|---|---|---|---|
| Comparative | 5 | connecting | 3 | 2 |
| Example 1 | | portion is absent | | |
| Comparative | 5 | opening is absent | 3 | 2 |
| Example 2 | | | | |

### Example 2

In Example 2, except that the width W₂ of the connecting portion of the reinforcing plate is set to about 1.67 mm (=W₀/3), ten samples similar to those of Example 1 are manufactured.

For the samples of Example 2, under similar conditions to those in Example 1, ten printed wiring boards are bent about a bending line and are plastic-deformed. Thereafter, whether the reinforcing plate peels off is verified.

As illustrated in Table 1, in Example 2, peeling off of the reinforcing plate does not occur in all samples.

### Example 3

In Example 3, except that the outside width W₀ of the bending subject portion of the wiring board main body is set to 1 mm, the outside width W₁ of the connecting portion of the reinforcing plate is also set to 1 mm, the distance L (that is, a length of the connecting portion) between the first reinforcing portion and the second reinforcing portion in the reinforcing plate is set to 1 mm, and the width W₂ of the connecting portion of the reinforcing plate is set to 0.1 mm (=W₀/10), ten samples similar to those of Example 1 are manufactured.

For the samples of Example 3, under similar conditions to those in Example 1, ten printed wiring boards are bent about a bending line and are plastic-deformed. Thereafter, whether the reinforcing plate peels off is verified.

As illustrated in Table 1, in Example 3, peeling off of the reinforcing plate does not occur in all samples.

### Example 4

In Example 4, except that the outside width W₀ of the bending subject portion of the wiring board main body is set to 1 mm, the outside width W₁ of the connecting portion of the reinforcing plate is also set to 1 mm, the distance L (that is, a length of the connecting portion) between the first reinforcing portion and the second reinforcing portion in the reinforcing plate is set to 1 mm, and the width W₂ of the connecting portion of the reinforcing plate is set to 0.33 mm (=W₀/3), ten samples similar to those of Example 1 are manufactured.

For the samples of Example 4, under similar conditions to those in Example 1, ten printed wiring boards are bent about a bending line and are plastic-deformed. Thereafter, whether the reinforcing plate peels off is verified.

As illustrated in Table 1, in Example 4, peeling off of the reinforcing plate does not occur in all samples.

### Example 5

In Example 5, except that the outside width W₀ of the bending subject portion of the wiring board main body is set to 1 mm, the outside width W₁ of the connecting portion of the reinforcing plate is also set to 1 mm, the distance L (that is, a length of the connecting portion) between the first reinforcing portion and the second reinforcing portion in the reinforcing plate is set to 5 mm, and the width W₂ of the connecting portion of the reinforcing plate is set to 0.10 mm (=W₀/10), ten samples similar to those of Example 1 are manufactured.

For the samples of Example 5, under similar conditions to those in Example 1, ten printed wiring boards are bent about a bending line and are plastic-deformed. Thereafter, whether the reinforcing plate peels off is verified.

As illustrated in Table 1, in Example 5, peeling off of the reinforcing plate does not occur in all samples.

### Example 6

In Example 6, except that the outside width W₀ of the bending subject portion of the wiring board main body is set to 1 mm, the outside width W₁ of the connecting portion of the reinforcing plate is also set to 1 mm, the distance L (that is, a length of the connecting portion) between the first reinforcing portion and the second reinforcing portion in the reinforcing plate is set to 5 mm, and the width W₂ of the connecting portion of the reinforcing plate is set to 0.33 mm (=W₀/3), ten samples similar to those of Example 1 are manufactured.

For the samples of Example 6, under similar conditions to those in Example 1, ten printed wiring boards are bent about a bending line and are plastic-deformed. Thereafter, whether the reinforcing plate peels off is verified.

As illustrated in Table 1, in Example 6, peeling off of the reinforcing plate does not occur in all samples.

### Example 7

In Example 7, except that the outside width W₀ of the bending subject portion of the wiring board main body is set to 10 mm, the outside width W₁ of the connecting portion of the reinforcing plate is also set to 10 mm, the distance L (that is, a length of the connecting portion) between the first reinforcing portion and the second reinforcing portion in the reinforcing plate is set to 1 mm, and the width W₂ of the connecting portion of the reinforcing plate is set to 1 mm (=W₀/10), ten samples similar to those of Example 1 are manufactured.

For the samples of Example 7, under similar conditions to those in Example 1, ten printed wiring boards are bent about a bending line and are plastic-deformed. Thereafter, whether the reinforcing plate peels off is verified.

As illustrated in Table 1, in Example 7, peeling off of the reinforcing plate does not occur in all samples.

### Example 8

In Example 8, except that the outside width W₀ of the bending subject portion of the wiring board main body is set to 10 mm, the outside width W₁ of the connecting portion of the reinforcing plate is also set to 10 mm, the distance L (that is, a length of the connecting portion) between the first reinforcing portion and the second reinforcing portion in the reinforcing plate is set to 1 mm, and the width W₂ of the connecting portion of the reinforcing plate is set to 3.33 mm (=W₀/3), ten samples similar to those of Example 1 are manufactured.

For the samples of Example 8, under similar conditions to those in Example 1, ten printed wiring boards are bent about a bending line and are plastic-deformed. Thereafter, whether the reinforcing plate peels off is verified.

As illustrated in Table 1, in Example 8, peeling off of the reinforcing plate does not occur in all samples.

### Example 9

In Example 9, except that the outside width W₀ of the bending subject portion of the wiring board main body is set to 10 mm, the outside width W₁ of the connecting portion of the reinforcing plate is also set to 10 mm, the distance L (that is, a length of the connecting portion) between the first reinforcing portion and the second reinforcing portion in the reinforcing plate is set to 5 mm, and the width W₂ of the connecting portion of the reinforcing plate is set to 1 mm (=W₀/10), ten samples similar to those of Example 1 are manufactured.

For the samples of Example 9, under similar conditions to those in Example 1, ten printed wiring boards are bent about a bending line and are plastic-deformed. Thereafter, whether the reinforcing plate peels off is verified.

As illustrated in Table 1, in Example 9, peeling off of the reinforcing plate does not occur in all samples.

### Example 10

In Example 10, except that the outside width W₀ of the bending subject portion of the wiring board main body is set to 10 mm, the outside width W₁ of the connecting portion of the reinforcing plate is also set to 10 mm, the distance L (that is, a length of the connecting portion) between the first reinforcing portion and the second reinforcing portion in the reinforcing plate is set to 5 mm, and the width W₂ of the connecting portion of the reinforcing plate is set to 3.33 mm (=W₀/3), ten samples similar to those of Example 1 are manufactured.

For the samples of Example 10, under similar conditions to those in Example 1, ten printed wiring boards are bent about a bending line and are plastic-deformed. Thereafter, whether the reinforcing plate peels off is verified.

As illustrated in Table 1, in Example 10, peeling off of the reinforcing plate does not occur in all samples.

### Comparative Example 1

In Comparative Example 1, except that the connecting portion is not provided in the reinforcing plate, ten samples similar to those of Example 1 are manufactured.

For the samples of Comparative Example 1, under similar conditions to those in Example 1, ten printed wiring boards are bent about a bending line and are plastic-deformed. Thereafter, whether the reinforcing plate peels off is verified.

As illustrated in Table 1, in Comparative Example 1, in eight samples out of ten samples, peeling off occurs in an end portion of the first reinforcing portion and an end portion of the second reinforcing portion.

### Comparative Example 2

In Comparative Example 2, except that an opening is not formed in the connecting portion of the reinforcing plate, ten samples similar to those of Example 1 are manufactured.

For the samples of Comparative Example 2, under similar conditions to those in Example 1, ten printed wiring boards are bent about a bending line and are plastic-deformed. Thereafter, whether the reinforcing plate peels off is verified.

As illustrated in Table 1, in Comparative Example 2, in all samples, peeling off of the reinforcing plate occurs in the bending line.

As described above, in Examples 1 to 10 where an opening is formed in the connecting portion of the reinforcing plate, it is possible to inhibit the reinforcing plate from peeling off due to bending. In particular, in Examples 3 to 10, it is confirmed that the peeling off of the reinforcing plate due to bending is inhibited by setting a ratio of outside widths W₂/W₀ to a value within a range of 1/10 to ⅓ when the outside width W₀ of the bending subject portion is 1 to 10 mm and the length L of the connecting portion is 1 to 5 mm.

On the other hand, in Comparative Example 1 where the connecting portion is not formed in the reinforcing plate, and in Comparative Example 2 where an opening is not formed in the connecting portion, peeling off of the reinforcing plate due to bending occurs.

### EXPLANATION OF REFERENCE NUMERALS

1 . . . printed wiring board
10 . . . wiring board main body
101 . . . bending subject portion
102 . . . first adjacent portion
103 . . . second adjacent portion
11 . . . base film
12 . . . wiring patterns
13 . . . coverlay
20 . . . reinforcing plate
201 . . . first reinforcing portion
202 . . . second reinforcing portion
203 . . . connecting portion
203a . . . opening

What is claimed is:

1. A printed wiring board, comprising:
a wiring board main body which includes a bending subject portion which is to be bent about a bending line; and
a reinforcing plate which is attached to the wiring board main body,
wherein the reinforcing plate includes:
first and second reinforcing portions which are attached to first and second adjacent portions which are adjacent to the bending subject portion in the wiring board main body; and
a connecting portion which is attached to the bending subject portion and integrally connects the first reinforcing portion with the second reinforcing portion, and
an opening is formed in the connecting portion.

2. The printed wiring board according to claim 1, wherein an outside width W₀ of the bending subject portion along the bending line is substantially equal to an outside width W₁ of the connecting portion along the bending line.

3. The printed wiring board according to claim 1, wherein the printed wiring board satisfies the following Inequality (1):
1/10≦W₂/W₀≦⅓ (1)
here, W₀ denotes an outside width of the bending subject portion along the bending line, and W₂ denotes a width of the connecting portion along the bending line in the above Inequality (1).

4. The printed wiring board according to claim 1, wherein the printed wiring board is bent in the bending subject portion.
